(19) United States
(12) Patent Application Publication
(10) Pub. No.: US 2026/0247753 A1
(43) Pub. Date: Aug. 20, 2026

(54) HETEROSTRUCTURES WITH TWO-DIMENSIONAL ACTIVE REGION

(71) Applicants: Ying Zhao, Ann Arbor, MI (US); Jun Song, Ann Arbor, MI (US); The Regents of the University of Michigan, Ann Arbor, MI (US)

(72) Inventors: David Arto Laleyan, Ann Arbor, MI (US); Woncheol Lee, Ann Arbor, MI (US); Ying Zhao, Montreal (CA); Yuanpeng Wu, Ann Arbor, MI (US); Jun Song, Montreal (CA); Emmanouil Kioupakis, Dexter, MI (US); Zetian Mi, Ann Arbor, MI (US)

(21) Appl. No.: 19/472,290

(22) PCT Filed: Apr. 4, 2024
(86) PCT No.: PCT/US2024/023036

§ 371 Date: Oct. 3, 2025

Related U.S. Application Data
(60) Provisional application No. 63/457,006, filed on Apr. 4, 2023.

(51) Int. Cl. H10H 20/825; H10H 20/01; H10H 20/812; H10H 20/818

(52) U.S. Cl. CPC H10H 20/825; H10H 20/01335; H10H 20/812; H10H 20/818

(57) ABSTRACT

A device includes a substrate and a heterostructure supported by the substrate, the heterostructure including a semiconductor stack supported by the substrate, the semiconductor stack defining a junction, and a nanostructure including a layered material, the nanostructure being disposed between the semiconductor stack and the substrate and configured such that radiative recombination of charge carriers reaching the nanostructure via the junction and the substrate is achieved.

### CROSS-REFERENCE TO RELATED APPLICATION

This application claims the benefit of U.S. provisional application entitled “Heterostructures with Two-Dimensional Active Region,” filed Apr. 4, 2023, and assigned Ser. No. 63/457,006, the entire disclosure of which is hereby expressly incorporated by reference.

### STATEMENT REGARDING FEDERALLY SPONSORED RESEARCH OR DEVELOPMENT

This invention was made with government support under Contract No. W911NF-17-1-0312 awarded by the U.S. Army Research Office and under Contract No. 1807984 awarded by the National Science Foundation. The government has certain rights in the invention.

### BACKGROUND OF THE DISCLOSURE

### Field of the Disclosure

The disclosure relates generally to heterostructures.

### Brief Description of Related Technology

Hexagonal boron nitride (h-BN) has drawn tremendous attention given its unique characteristic of being a two-dimensional (2D) quantum material, making it a fundamental building block of van der Waals heterostructures for future nanoscale electronic, photonic, and quantum devices. Little attention, however, has been paid to the ultrawide bandgap nature of h-BN and the formation of heterostructures with Al(Ga)N-based semiconductors. However, progress in developing devices utilizing conventional Al(Ga)N materials has been severely limited by transverse magnetic (TM) polarized emission, the strong polarization field, and the presence of extensive defects, which lead to extremely low quantum efficiency and poor light extraction efficiency.

The synthesis of highly crystalline h-BN has been a topic of extensive study. Bulk single-crystal growth is mainly achieved either using a high-pressure, high-temperature (HPHT) method, or at atmospheric pressure using molten metal solvents such as Ni or Fe. In addition, 2D h-BN, due to van der Waals bonding, can be potentially grown as a thin film on foreign substrates without the formation of dislocations. h-BN, however, is an indirect bandgap semiconductor like Si. In such indirect bandgap semiconductors, the near band-edge optical transitions involve phonons, thereby resulting in orders of magnitude lower quantum efficiency than direct bandgap semiconductors. Recent studies on the luminescence emission of h-BN have been largely limited to defect-related emission, which has only been exploited as single photon source operating in the visible or near-UV spectrum. While there have been reports of luminescence from near band-edge transitions in h-BN, including cathodoluminescence (CL), photoluminescence (PL) and most recently electroluminescence (EL), an unresolved fundamental challenge is whether, and how an indirect bandgap semiconductor can be transformed to be an efficient light emitter.

### SUMMARY OF THE DISCLOSURE

In accordance with one aspect of the disclosure, a device includes a substrate, and a heterostructure supported by the substrate. The heterostructure includes a semiconductor stack supported by the substrate, the semiconductor stack defining a junction, and a nanostructure including a layered material. The nanostructure is disposed between the semiconductor stack and the substrate and configured such that radiative recombination of charge carriers reaching the nanostructure via the junction and the substrate is achieved.

In accordance with another aspect of the disclosure, a device includes a substrate, and a heterostructure supported by the substrate. The heterostructure includes a semiconductor stack supported by the substrate, the semiconductor stack defining a junction, and a two-dimensional active region disposed between the semiconductor stack and the substrate. The two-dimensional active region is configured for photoemission upon charge carriers reaching the two-dimensional active region via the junction.

In accordance with yet another aspect of the disclosure, a method of fabricating a device includes forming a nanostructure on a substrate, the nanostructure including a layered material, and forming a semiconductor stack on the nanostructure such that the nanostructure is disposed between the semiconductor stack and the substrate, such that the semiconductor stack defines a junction, and such that radiative recombination of charge carriers reaching the nanostructure via the junction and the substrate is achieved.

In accordance with still yet another aspect of the disclosure, a light emitting device includes a substrate and a heterostructure supported by the substrate. The heterostructure includes an active region configured for photoemission. The active region includes hexagonal boron nitride.

In connection with any one of the aforementioned aspects, the devices and/or methods described herein may alternatively or additionally include or involve any combination of one or more of the following aspects or features. The nanostructure has a bandgap such that the radiative recombination emits far UV-C light. The semiconductor stack and the nanostructure are configured to establish a light emitter. The semiconductor stack and the nanostructure are configured to establish a single photon source. The nanostructure is configured as a two-dimensional active region. The layered material is an indirect bandgap semiconductor material. The layered material has an ultrawide bandgap. The layered material includes hexagonal boron nitride. The nanostructure is a monolayer of the layered material. The junction is defined by a p-i-n layer arrangement of the semiconductor stack. The semiconductor stack includes a layer of a wide bandgap semiconductor material. The substrate includes nickel. The semiconductor stack includes a plurality of layers, each layer of the plurality of layers including a Ill-nitride semiconductor material. The semiconductor stack includes a nanowire that projects outwardly from the substrate. The nanostructure is in contact with the substrate. The nanostructure is in contact with the semiconductor stack. The two-dimensional active region is configured as a monolayer. The two-dimensional active region includes an indirect bandgap semiconductor material. The two-dimensional active region includes hexagonal boron nitride. The semiconductor stack includes a layer of a wide bandgap semiconductor material. The two-dimensional active region is in contact with the substrate. The two-dimensional active region is in contact with the semiconductor stack. Forming the nanostructure includes growing the nanostructure epitaxially. Forming the semiconductor stack includes growing a plurality of semiconductor layers of the semiconductor stack epitaxially.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts graphical plots of (a) interfacial energies for h-BN on different substrates, (b) boron and nitrogen vacancy formation energies under boron-rich and nitrogen-rich conditions, and (c) formation energies of boron and nitrogen vacancies in h-BN supported on a Ni (111) substrate under nitrogen-rich and boron-rich conditions, determined using various supercell sizes n (in all vacancy determinations, only one vacancy was created in a supercell).

FIG. 2 depicts graphical plots of (a) photoluminescence (PL) spectra of h-BN on a Ni (111) substrate at 20 K and 300 K, and (b) estimated internal quantum efficiency (IQE) of the h-BN on Ni (111) at various excitation powers, with dashed lines as a guide.

FIG. 3 depicts graphical plots of (a) the quasi-particle band structure and interband dipole matrix elements of bulk h-BN, with the direct optical transition at the CBM location (k=M) being dipole-forbidden due to the symmetry of the crystal, and with a strong transition dipole moment predicted for the VBM location (k of about K), (b) exciton dispersion relation of h-BN obtained from the Bethe-Salpeter equation (red, lower curve) compared to the excitation energy of independent quasiparticles obtained from GW calculations (blue, upper curve), in which the lowest energy indirect exciton state is at a q of 5 q₀ or about 0.7 A⁻¹, located 65 eV below the direct exciton state, and (c) spontaneous emission spectrum of bulk h-BN and bulk AlN, in which the red and blue dashed lines indicate the lowest energy indirect and direct exciton states of h-BN and AlN, respectively, and in which the arrows indicate the energy of the phonon modes that contribute to the phonon-assisted emission of h-BN.

FIG. 4 depicts (a) a schematic view of an example LED device having a p-i-n AlN-based stack on a h-BN nanostructure on a Ni substrate in which the Ni substrate acts as a p-contact, and Ti/Au metal pads act as n-contacts on top of an n-AlGaN contact layer, (b) a schematic view of the operation of the example LED device, where recombination occurs in the h-BN nanostructure due to electron overflow, (c, d) SEM images of the h-BN/Ni interface before and after AlN regrowth, in which the h-BN features are colored in yellow, and remain noticeable and unchanged under the comparatively thick AlN.

FIG. 5 depicts graphical plots of (a) the I-V characteristic of a device having a heterostructure with a nanostructure or two-dimensional active region disposed between a semiconductor stack and a substrate in accordance with one example (in this example, a 1 mm×1 mm AlN/h-BN/Ni LED device), with a photograph of the device being probed as an inset, (b) room-temperature electroluminescence (EL) spectra of the emissions at about 220 nm from the LED device at various injection currents, and (c) the room-temperature EL spectrum of the LED device overlapped with the low-temperature PL spectrum of a h-BN/Ni structure.

FIG. 6 is a flow diagram of a method of fabricating a device having a heterostructure with a nanostructure or two-dimensional active region disposed between a semiconductor stack and a substrate in accordance with one example.

The embodiments of the disclosed devices and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Devices having a heterostructure with a nanostructure or two-dimensional active region disposed between a semiconductor stack and a substrate are described. Photoemission or radiative recombination is achieved upon charge carriers reaching the nanostructure or two-dimensional active region via a junction defined by the semiconductor stack. In some cases, the nanostructure or two-dimensional active region is composed of hexagonal boron nitride (h-BN). The h-BN is useful and well-suited to form heterostructures with Ill-nitride semiconductor materials, such as Al(Ga)N-based semiconductors. Methods of fabricating heterostructures are also described.

The radiative recombination or photoemission of the disclosed devices may be used to realize a wide variety of devices, including classical and non-classical devices. For instance, various types of light emitters, as well as single photon sources, may be realized. The nanostructures or two-dimensional active regions may be configured such that the radiative recombination emits for UV-C light.

The semiconductor-based quantum heterostructures of the disclosed devices are well-suited for solid-state UV lamps, which provide a useful alternative to conventional mercury and xenon lamps for many applications, including the disinfection and sterilization of infectious diseases, such as severe acute respiratory syndrome coronavirus 2 (SARS-CoV-2)9. While conventional germicidal lamps emit at wavelengths of about 260 nm that are hazardous to humans, far UV-C emitters (about 207 to about 222 nm) do not have sufficient range to penetrate through the outer layer of the eye and skin, but retain the germicidal properties to inactivate microbes and can therefore operate continuously in public areas.

In some cases, the substrate of the disclosed devices is composed of, or otherwise includes, nickel (Ni). Nickel serves as a useful substrate for h-BN due to minimal lattice mismatch and optimal interfacial interactions.

The disclosed devices exploit strong excitonic effects and efficient exciton-phonon coupling to allow an indirect bandgap semiconductor such as h-BN to establish a high efficiency far UV-C light emitter. The room temperature internal quantum efficiency was measured to be 60% in the far UV-C (about 220 nm), which is orders of magnitude higher than that of any other known indirect bandgap semiconductors. This disclosed devices provide both far UV-C light sources for safe and energy-efficient ultraviolet sterilization of disease pathogens, as well as quantum optoelectronic and electronic devices utilizing the 2D semiconductor materials.

The term “nanostructure” is used herein to include structures of a variety of shapes. The nanostructures may or may not be elongated in a particular lateral dimension. The term is also used with the understanding that one or more dimensions (e.g., length or width) of the structure may be larger than nanoscale, but nonetheless constitute a nanostructure due to the nanoscale thickness of the structure.

Although described in connection with light emitting and/or optoelectronic devices, the disclosed methods and devices may be applied to a wide variety of electronic and other devices. For instance, the disclosed devices may be configured for quantum computing and other functions and applications.

Although described in connection with examples having p-i-n junction heterostructures, the disclosed devices and methods may include or involve heterostructures of varying construction, configuration, and composition. For instance, the disclosed methods and devices may include or involve any number of additional layers, structures, or elements, including, for instance, Ill-nitride structures (e.g., GaN, InN, AlN, and their alloys), other III-V structures, or other semiconductor structures.

The compositions of other elements or components of the disclosed devices may also vary. For instance, the disclosed devices are not limited to a particular substrate material or a particular type of semiconductor material. While the disclosed devices and methods are described in connection with nickel substrates, other substrate materials may be used, including, for instance, graphene, highly ordered pyrolytic graphite (HOPG), sapphire, Cu, and SiC.

While the disclosed devices and methods are described in connection with hBN nanostructures, other layered materials may be used, including, for instance, Molybdenum disulfide (MoS₂), Molybdenum diselenide (MoSe₂), Tungsten disulfide (WS₂), Tungsten diselenide (WSe₂), and graphene.

The substrate of the disclosed devices may or may not correspond with the growth substrate, or the substrate on which the heterostructures of the disclosed devices are grown. For instance, the heterostructures may be transferred to another substrate, such as a GaN, Si, or sapphire substrate, after growth of the heterostructures.

The substrate may or may not have a composition in common with a layered material of the heterostructure. For instance, the substrate may be composed of, or otherwise include, graphene, GaN, AlN, or their alloys, sapphire, and SiC, while the layered material may be composed of, or otherwise include, graphene, MoS₂, WS₂, or WSe₂.

The configuration, construction, fabrication, and other characteristics of the heterostructures may also vary from the examples described. For instance, the heterostructures may include any number of epitaxially grown layers.

Although described in connection with MBE growth procedures, additional or alternative non-sputtered epitaxial growth procedures may be used. For instance, metal-organic chemical vapor deposition (MOCVD) and hydride vapor phase epitaxy (HVPE) growth procedures may be used. Still other procedures may be used, including, for instance, pulsed laser deposition procedures.

Conventional high efficiency light emitting diode (LED) devices are realized by growing on single crystalline substrates, such as sapphire, SiC, GaAs, and InP. In this regard, the epitaxy of h-BN on crystalline semiconducting substrates such as sapphire and AlN has been studied.

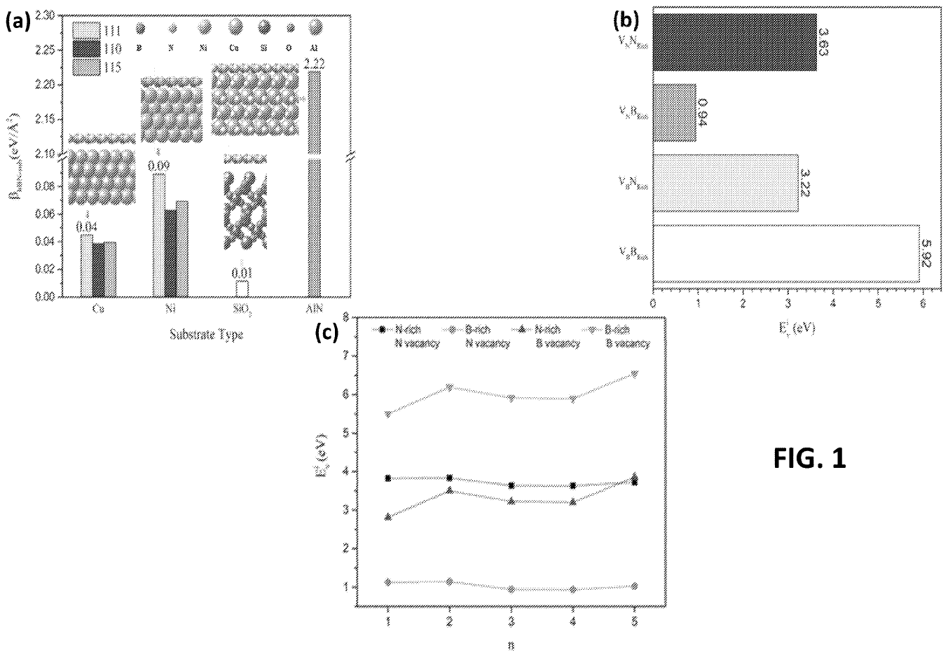

First-principles density functional theory (DFT) calculations were performed to investigate the heterointerface between monolayer h-BN and various substrates, including sapphire, AlN, SiOₓ, as well as Ni and Cu. The results indicated that, besides the minimal lattice mismatch (about 0.5%) with h-BN, Ni exhibits useful interfacial interaction with h-BN (i.e., adhesion energy, β_{hBN-sub}, among other studied systems (see FIG. 1, part a). As shown in FIG. 1, part a, different Ni facets show consistently good interfacial interaction with h-BN without inducing notable distortion in the h-BN structure. The nanostructures of the disclosed devices may thus be formed on polycrystalline Ni.

In sharp contrast, SiO₂ shows very weak interaction with h-BN as evidenced by near-zero β_{hBN-sub}, while sapphire and AlN interact very strongly with h-BN, inducing considerable distortion in h-BN lattice. Consequently, one would expect it to be difficult for h-BN to nucleate and grow on SiO₂, whereas h-BN grown on sapphire is expected to be highly defective.

In addition to theoretically evaluating the effect of the substrate composition and other characteristics, the impact of the chemical environment for h-BN growth was also investigated. One notable aspect is vacancy formation, which is of direct implication to the quality of h-BN. As shown in FIG. 1, part b, under B-rich environments, the formation energy of N vacancies for substrate-supported h-BN is very small, about 0.94 eV, thereby leading to the presence of extensive N vacancies. Under N-rich conditions, however, the formation energies for both B and N vacancies are very large, about 3.5 and about 4 eV, respectively. Therefore, high quality h-BN is preferentially grown under N-rich, instead of B-rich growth conditions. The nanostructures of the disclosed devices may thus be grown in N-rich conditions.

Meanwhile, the effect of supercell size on the single vacancy formation energy was also examined, with the results shown in FIG. 1, part c, where n corresponds with a supercell of size n×n. As shown in FIG. 1, part c, the B vacancy shows the lowest formation energy at the smallest supercell (i.e., n=1), while for the N vacancy, its formation energy decreases as the supercell size increases until n equals 3 and stabilizes for n greater than 3. As the vacancy density is inversely proportional to the supercell size, it is concluded that the B vacancy tends to form at a very high density (i.e., n equal to 1), while the N vacancy is more likely to form at lower densities.

The epitaxy of h-BN on various substrates under N-rich epitaxy conditions was experimentally investigated. Unannealed polycrystal Ni metallic wafers with dimensions 2″×2″×1 mm, were used as the substrate for some examples described herein. These wafers were directly loaded from their vacuum packaging into the load-lock of the MBE system without any wet processing to avoid the surface oxidation of Ni. The wafers were thermally outgassed prior to transferring into the growth chamber. After being loaded into the growth chamber, the Ni wafer was ramped up to 800° C. (thermocouple temperature reading, with real surface temperature estimated to be about 1100° C.) and maintained for 30 minutes to thermally desorb the surface native oxide. Using a relatively low B deposition rate (e.g., less than 0.05 Å/s) and nitrogen-rich plasma parameters (e.g., a flow rate of 1.5 sccm with a forward power of 350 W). The growth durations were between 30 minutes and 1 hour in these examples. Growth was conducted using a Veeco GENxplor radio frequency (RF) nitrogen plasma-assisted MBE system equipped with an e-beam evaporation source for elemental boron (99.999% purity).

Further details regarding the growth of h-BN on Ni (e.g., Ni (111) are set forth in Laleyan, D. A. et al., “Effect of growth temperature on the structural and optical properties of few-layer hexagonal boron nitride by molecular beam epitaxy,” Opt. Express 26, 23031-23039 (2018), the entire disclosure of which is hereby incorporated by reference.

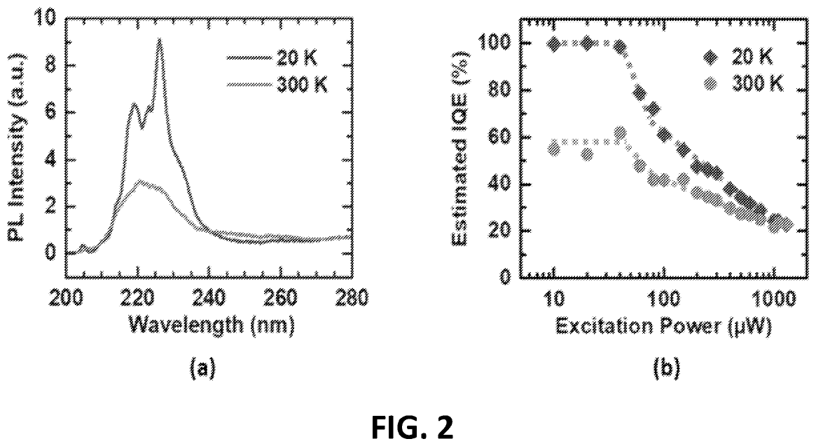

The epitaxy of h-BN on an Ni substrate exhibited drastically different properties than growth directly on sapphire and SiO₂. It was also observed that h-BN grown directly on sapphire and SiO₂ is dominated by defect-related emission across the UV bands. In contrast, when grown on an Ni substrate, at room temperature, the PL emission is dominated by deep UV excitonic emission, with suppressed defect-related emission. The optical properties of the epitaxial h-BN on Ni were further characterized using variable excitation power and temperature-dependent PL spectroscopy. The representative PL spectra are shown in FIG. 2, part a. At cryogenic temperature, distinct peaks are resolved at about 220 nm.

The quantum efficiency of h-BN deep UV emission was derived from temperature and power-dependent photoluminescence spectroscopy. Based on previous studies of GaN-based LED structures, the highest internal quantum efficiency measured at cryogenic temperature (e.g., 20 K) is assumed to be unity, due to the suppression of nonradiative recombination. The internal quantum efficiency measured at different temperatures and excitation powers can then be obtained by taking the ratio of luminescence efficiency, defined as the integrated luminescence intensity vs. excitation power, with respect to the highest value measured at cryogenic temperature. It is worth noting that while the optical transition in h-BN is indirect and therefore phonon dependent, which may in principle be inefficient at low temperature, this transition is in fact assisted by phonon emission, which is not sensitive to temperature. Remarkably, as shown in FIG. 2, part b, the room-temperature internal quantum efficiency for the epitaxial h-BN reached 60%, which is orders of magnitude higher than that of any other indirect bandgap materials and is comparable to, or better than, direct bandgap semiconductors commonly used in commercial LEDs and laser diodes. It was also observed that the efficiency remains relatively constant under low to moderate excitation conditions, which is consistent with exciton dominated emission. Moreover, the internal quantum efficiency shows a droop with increasing excitation power, which is due to enhanced Auger recombination, or other higher order carrier loss terms under high excitation conditions. Similar efficiency droop has been commonly measured in GaN-based LEDs.

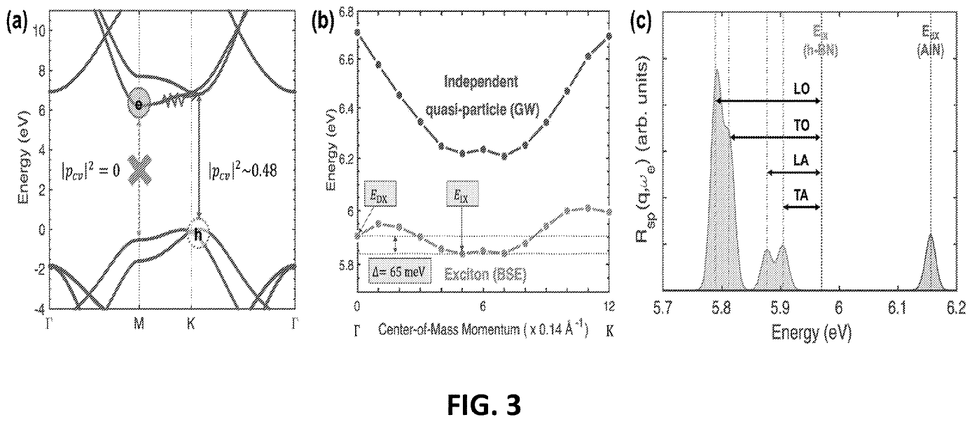

Unlike h-BN, conventional indirect-bandgap semiconductors exhibit extremely low luminescence efficiency, preventing their application in LEDs. In this regard, a detailed theoretical study of the origin for the high luminescence efficiency of indirect-bandgap h-BN using first-principles calculations was performed. First, the band calculations predict an indirect gap of 6.22 eV between the conduction band minimum (CBM) at the M point, and the valence band maximum (VBM) close to the K point, as shown in FIG. 3, part a. In addition, the interband dipole matrix element value is calculated to be zero at the M point, implying that the direct optical transition is forbidden at this point. Meanwhile, a strong dipole matrix element value is observed at the VBM location. Therefore, the phonon-assisted indirect radiative recombination process involves the emission of phonons of wavevector q=MK followed by interband optical emission at the K point. Based on the band structure analysis, the luminescence intensity of indirect optical transitions in h-BN was investigated by considering the relevant electron phonon scattering processes. Using second-order perturbation theory, the transition matrix element S for this phonon-assisted transition can be written as

$${S}^{2} = \frac{{M}_{dX}^{2} {M}_{ephX}^{2}}{{( {E}_{d} - {E}_{i} + ℏ {ω}_{p h} )}^{2}} \qquad ( 1 )$$

where M_{dX} is the direct optical transition matrix element, M_{ephX} is the exciton-phonon coupling matrix elements, E_{d} and Eᵢ is the energy of direct and indirect transition, ℏΩₚₕ is the phonon energy involved in the phonon-assisted transition. First, the direct optical transition matrix element (or the oscillator strength of direct excitons) can be deduced from the size of the excitons. Based on the values of the exciton Bohr radius

$$( {a}_{X}^{B N} = 8 Å , {a}_{X}^{A l N} = 15 Å )$$

and the Wannier-Mott model, which predicts

$${M}_{d X}^{2} ∝ 1 / {a}_{X}^{3} ,$$

it is estimated that the oscillor strength of direct excitons of h-BN is approximately one order of magnitude higher than in AlN. The strong oscillator strength of h-BN indicates exceptionally strong light-matter interaction, which has been attributed to the quasi-2D nature of excitons in h-BN.

Density-functional perturbation theory (DFPT) calculations were also performed to analyze the electron-phonon scattering processes, which assist indirect optical transitions in h-BN. From DFPT, the electron-phonon matrix elements are defined as—

$${g}_{m n v}^{k , q} = 〈 {u}_{m k + q} \vert {Δ}_{q v} {ν}^{K S} \vert {u}_{n k} 〉 \qquad ( 2 )$$

where uₙₖ represents the Bloch components of electron wavefunctions for the band index n and the electron wavevector k, and Δ_{gv}v^{KS} is the phonon-induced variation of the self-consistent potential v^{KS} with respect to the phonon wavevector q and the phonon branch index v. The relevant phonon scattering processes were considered, where electrons at CBM (k=M) are scattered by the phonons with momentum q=\vec{MK} and transferred to the K point. Several phonon branches exhibit coupling intensity of the order of a few tens of meV. In particular, the strongest electron-phonon coupling is predicted for the longitudinal optical phonon (LO), (|g_{LO}|=111 meV). For charge-neutral excitons, electron-phonon and hole-phonon coupling can compensate each other so that the exciton-phonon may show less significant coupling. However, because the hole-phonon scattering contribution is negligible for the indirect excitons in this case, both electron-phonon matrices and exciton-phonon matrices are expected to be of similar magnitude.

The exciton calculation predicts the flattening of the exciton dispersion relation in h-BN, as shown in FIG. 3, part b. The calculation confirms that the lowest-energy indirect exciton state is mainly formed by the indirect electron-hole pairs near the band extrema. In particular, the calculated energy difference between the direct and indirect transition is merely 65 meV, in good agreement with the experimental value of 70 meV. This value is much smaller than the values of other indirect-gap materials, such as silicon or diamond. Thus, the sum of all energy terms in the denominator of S is still comparable to the magnitude of the electron-phonon coupling matrix for h-BN. Therefore, the strong electron-phonon coupling and the flat exciton dispersion promotes bright luminescence for h-BN even though it is an indirect-gap material.

Strong photoemission from h-BN was also confirmed by directly calculating the phonon-assisted optical absorption and emission spectra of bulk h-BN. The special displacement method, where the atoms in a large supercell are displaced to incorporate the electron-phonon interactions was adopted. Also, the detailed balance principle was invoked to obtain the spontaneous emission rate. FIG. 3, part c, shows the spontaneous emission rate of h-BN and AlN. Compared to the absorption spectrum, the emission peaks of h-BN are shifted to the lower-energy side of the indirect exciton state, showing the mirror symmetry between the indirect absorption and emission processes. Also, bulk h-BN is predicted to exhibit much higher spontaneous emission rate than bulk AlN, directly indicating its high luminescence efficiency. The relative intensity and the position of each emission peak matched well with the previously reported PL spectrum.

Several other factors may be considered to support the high luminescence efficiency of h-BN. First, non-radiative processes can compete with the radiative process and suppress the luminescence efficiency. For h-BN, the radiative recombination time is experimentally proven to occur at the sub-nanosecond scale, owing to the efficient exciton-phonon interactions. Efficient exciton-phonon interaction and a strong exciton oscillator strength, caused by extremely flat bands along c-axis, attributed to the 2D nature of h-BN, enables very fast radiative recombination processes. Thus, for high-quality h-BN, it is fast enough to bypass many nonradiative recombination processes. In addition to the internal quantum efficiency, the extraction efficiency is also a performance parameter of UV LEDs. In the case of bulk AlN or Al-rich AlₓGa₁₋ₓN alloys, TM-polarized light emission has been considered as a bottleneck in the development of high-efficiency DUV LEDs. Meanwhile, from polarization-resolving PL, it was found that h-BN exhibits predominantly transverse electric (TE) polarized light emission, which is useful for efficient light extraction. Furthermore, the indirect bandgap of h-BN leads to a Stokes shift between the absorption and emission spectra, and prevents the re-absorption of the emitted photons, which is known to severely suppress the extraction efficiency for direct-bandgap semiconductors. These factors provide unambiguous evidence that h-BN exhibits bright luminescence intensity, even stronger than AlN, despite the indirect nature of its bandgap.

Described herein are devices in which h-BN, despite its indirect bandgap, exhibits remarkably high luminescence emission efficiency at room temperature, which is explained by strong electron-phonon coupling and excitonic effects. In some examples, a Ni substrate serves as a useful substrate for h-BN growth due to minimal lattice mismatch and optimal interfacial interactions. Moreover, the achievement of wafer-scale superior quality h-BN supports applications in deep UV optoelectronics, high-frequency, and high-power electronics, as well as a broad range of nanoscale electronic and quantum devices and systems.

The disclosed devices are configured for efficient charge carrier (both electrons and holes) injection into the 2D h-BN nanostructure or active region. Electrically injected devices may thus be realized. To date, the realization of efficient current conduction of ultrawide bandgap semiconductor materials such as h-BN has remained extremely challenging. In addition, effective current injection from a conventional 3D metal contact to a 2D semiconductor has remained a subject of intensive study.

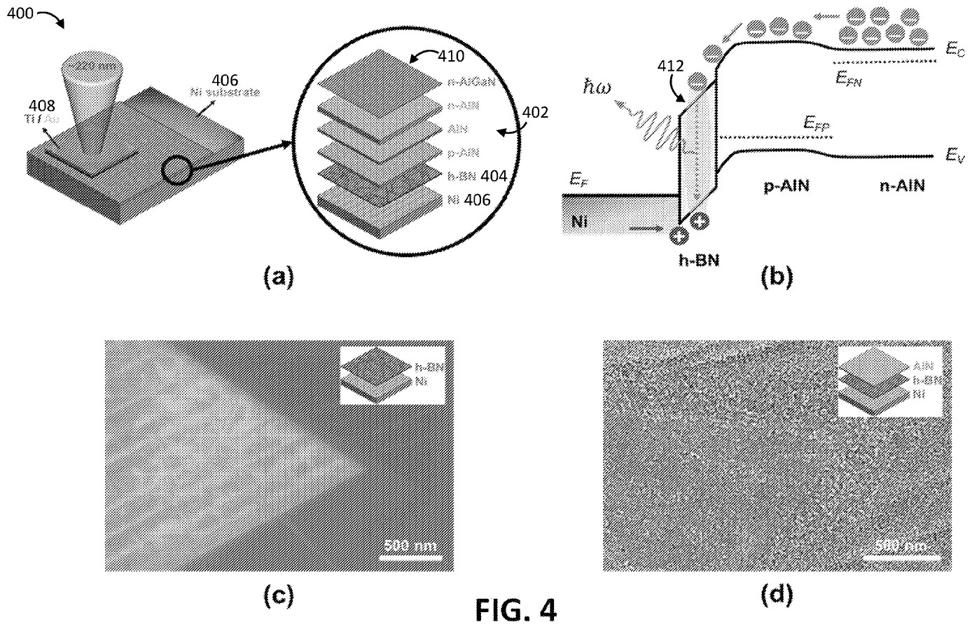

As shown in FIG. 4, to overcome these limitations and challenges, a device 400 in accordance with one example includes a heterostructure with a semiconductor stack that defines a junction, and a two-dimensional active region (or a nanostructure composed of, or otherwise including, a layered material, such as h-BN) disposed and configured for photoemission upon charge carriers reaching the two-dimensional active region (or nanostructure) via the junction. Radiative recombination of charge carries reaching the two-dimensional active region (or nanostructure) via the junction is achieved. Further details regarding the example shown in FIG. 4 are set forth below.

As shown in FIG. 4, the LED device 400 has a p-i-n AlN-based stack 402 on a h-BN nanostructure 404 on a Ni substrate 406 in which the Ni substrate 406 acts as a p-contact, and in which Ti/Au metal pads 408 act as n-contacts on top of an n-AlGaN contact layer 410. As described herein, recombination occurs in the h-BN nanostructure 404 due to electron overflow. Parts (c) and (d) of FIG. 4 are SEM images of the h-BN/Ni interface before and after AlN regrowth, in which the h-BN features are colored in yellow (or indicated at 412), and remain noticeable and unchanged under the comparatively thick AlN.

As described herein, the semiconductor stack 402 is supported by the substrate 406. The substrate 406 may be composed of, or otherwise include, nickel, but alternative or additional materials may be used. In some cases, the semiconductor stack 402 may be configured as, or otherwise include, a nanowire that projects outwardly from the substrate 406. Alternative or additional shapes or configurations may be used.

As described herein, the semiconductor stack 402 defines a junction. The junction may be defined by a p-i-n layer arrangement of the semiconductor stack 402. The semiconductor stack 402 may include a plurality of layers, each layer of the plurality of layers being composed of, or otherwise including, a Ill-nitride semiconductor material. For instance, the semiconductor stack 402 may include a layer of a wide bandgap semiconductor material, such as AlN, but alternative or additional materials may be used.

As described herein, the nanostructure 404 is composed of, or otherwise includes, a layered material. The nanostructure 404 is disposed between the semiconductor stack 402 and the substrate 406. The nanostructure 404 is configured such that radiative recombination of charge carriers reaching the nanostructure 402 via the junction and the substrate 406 is achieved. In some cases, the nanostructure 404 may be configured as, or otherwise include, a two-dimensional active region disposed between the semiconductor stack 402 and the substrate 406, such that the two-dimensional active region is configured for photoemission upon charge carriers reaching the two-dimensional active region via the junction.

As described herein, the layered material may be an indirect bandgap semiconductor material. In some cases, the layered material has an ultrawide bandgap. For instance, the layered material is or includes hexagonal boron nitride. The two-dimensional active region may accordingly be composed of, or otherwise include, hexagonal boron nitride. In some cases, the nanostructure 404 (or two-dimensional active region) is configured as, or constitutes, a monolayer of the layered material.

As shown in the example of FIG. 4, the nanostructure 404 may be in contact with the substrate 406. As also shown, the nanostructure 404 may be in contact with the semiconductor stack 402.

As described herein, the two-dimensional active region (or nanostructure) may have a bandgap such that the radiative recombination emits far UV-C light. In some cases, the semiconductor stack 402 and the nanostructure 404 are configured to establish a light emitter. In other cases, the semiconductor stack 402 and the nanostructure 404 are configured to establish a single photon source.

The layered material of the nanostructure 404 may be an indirect bandgap semiconductor material. Alternatively or additionally, the layered material may have an ultrawide bandgap. In some cases, the layered material of the two-dimensional active region (or nanostructure 404) is composed of, or otherwise includes, h-BN.

The thickness of the nanostructure 404 may vary. In some cases, the nanostructure 404 is a monolayer of the layered material. In other cases, a few layers of the layered material may be used.

In some cases, the junction is defined by a p-i-n layer arrangement of the semiconductor stack 402. The semiconductor stack 402 may include one or more layers of a wide bandgap semiconductor material. For instance, one or more layers may be composed of AlN and/or alloys thereof. The semiconductor stack 402 may be configured as a nanowire that projects outwardly from the substrate. The shape, size, configuration, and other characteristics of the junction may vary, including, for instance, the composition of the respective layers of the semiconductor stack 402. For instance, other III-nitride semiconductor materials may be used.

In some cases, the substrate 406 is composed of, or otherwise includes, nickel. The nickel may be single crystalline or poly-crystalline. The substrate 406 may be of uniform or composite construction. Additional or alternative materials may be thus be used.

As shown in the example of FIG. 4, the nanostructure 404 may be in contact with the substrate 406. The nanostructure 404 may additionally or alternatively be in contact with the semiconductor stack 402.

FIG. 4, part a, schematically shows the configuration and operation of the example device 400. In this example, the device 400 has a h-BN-based LED structure with a h-BN nanostructure 404 on a Ni substrate 406 and a semiconductor stack 402 that defines a junction grown on top. In this example, the semiconductor stack 402 includes a coalesced AlN nanowire p-n junction, and the Ni substrate 406 serves as a p-contact for hole injection into the h-BN active region 404. Electron injection into the h-BN active region 404 is achieved from a top Ti/Au metal contact 408 by exploiting the unique electron overflow effect of the AlN p-n junction. Electron overflow dominates the current injection of the AlN-based p-n junctions. As a result, electrons injected from the n-metal contact 408 can readily flow to the h-BN active region 404 through the p-n junction. The utilization of the AlN p-n junction, instead of a single n-type AlN electron injection layer, helps to confine holes into the thin h-BN active region 404.

The operation and energy band diagram of the example LED device 400 is further shown in FIG. 4, part b. Scanning electron microscope (SEM) images show the h-BN domains on Ni (see FIG. 4, part c) and the sample surface after the Al(Ga)N regrowth (see FIG. 4, part d). Interestingly, the h-BN features are still perceptible, given the morphological differences of AlN grown on the h-BN domains or elsewhere. This indicates that the underlying h-BN remained unaffected by the growth of the AlN nanowires

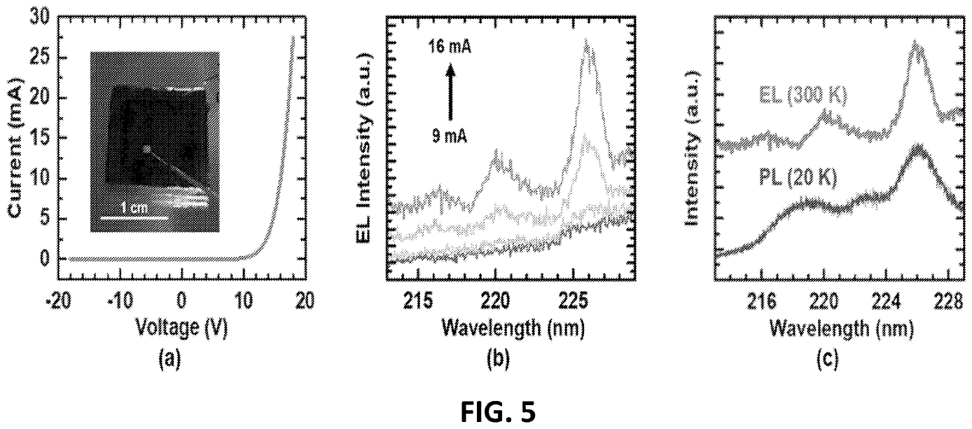

Examples of h-BN far UV-C LED devices were fabricated by depositing topside n-metal contacts. Further details regarding the fabrication of the example devices are provided below. FIG. 5, part a, shows the current-voltage (I-V) characteristics of a 1 mm×1 mm device, with its photograph while under operation shown in the inset. The device exhibits excellent I-V characteristics, with very low leakage current under reverse bias. The device turn-on voltage is about 12 V. For comparison, previously reported AlN far UV-C LEDs exhibited turn-on voltages as high as 20-30 V.

Shown in FIG. 5, part b, are the electroluminescence spectra of the device measured at room temperature under various electrical injection conditions. The electroluminescence peaks resolve at relatively high injection only, which agrees with the LED design based on electron overflow for getting the electrons to recombine in the h-BN active region.

FIG. 5, part c, shows that the device exhibited electroluminescence emission at about 220 nm, which is consistent with the previous reports of PL (and CL) of pristine h-BN. Furthermore, an identical control sample, but without the incorporation of a h-BN active region, was grown, fabricated, and characterized. While the control sample exhibited the I-V characteristics of an LED, it did not show any emission at about 220 nm, further providing unambiguous evidence that the electroluminescence emission originated from the h-BN. Moreover, the I-V and light-emission characteristics were monitored over a period greater than one year with the samples stored at atmosphere. The performance of these devices remained virtually unchanged.

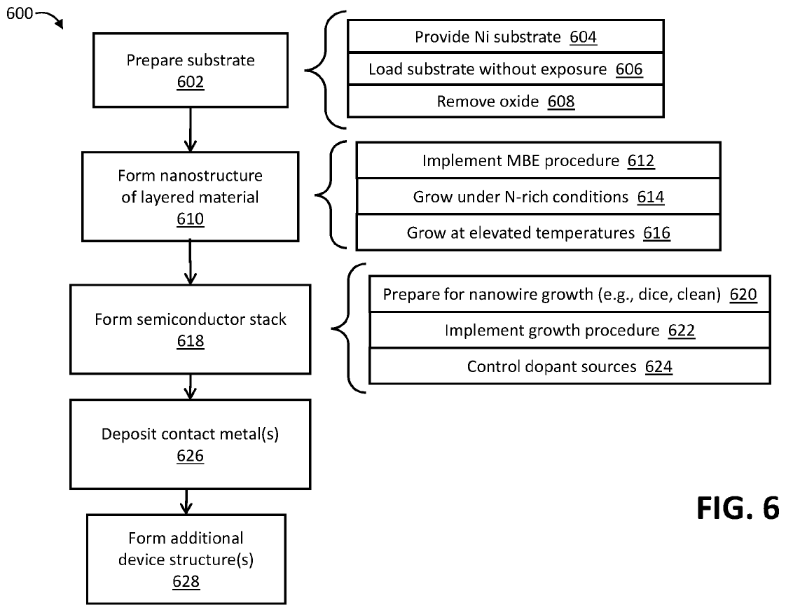

FIG. 6 depicts a method 600 of fabricating a device having a heterostructure with a nanostructure or two-dimensional active region disposed between a junction-defining semiconductor stack and a substrate in accordance with one example. As described herein, the method 600 may be configured such that a photoemission or radiative recombination is achieved upon charge carriers reaching the two-dimensional active region or nanostructure via the junction. The device may be configured as a light emitter or other optoelectronic device, or a single photon source or other quantum device. The method 600 may be used to fabricate the device examples described herein, as well as other heterostructures and devices.

The method 600 may begin with an act 602 in which a substrate (e.g., growth substrate) is prepared and/or otherwise provided. In some cases, the act 602 includes providing a Ni substrate in an act 604. For instance, the substrate may be composed of, or otherwise include, a polycrystalline or single crystalline Ni substrate. Alternative or additional materials may be used as described above.

The substrate may be loaded into a growth system without wet processing or other exposure (e.g., to the ambient) in an act 606. For example, Ni wafers may be directly loaded from vacuum packaging into the load-lock of an MBE system. The lack of processing and exposure may be useful for avoiding or limiting oxidation. Any oxide present on the surface of the substrate may be removed in an act 608. In some cases, the wafers may be thermally outgassed prior to transfer into the growth chamber of the MBE system. In one example, after loaded into the growth chamber, the Ni wafer was ramped up to 800° C. (thermocouple temperature reading, with real surface temperature estimated to be about 1100° C.) and maintained for 30 minutes to thermally desorb the surface native oxide.

Additional or alternative processing may be implemented in other cases, including, for instance, doping or deposition procedures. The substrate thus may or may not have a uniform composition. The substrate may be a uniform or composite structure.

In an act 610, a nanostructure is formed on the substrate. The nanostructure is composed of, or otherwise includes, a layered material, such as h-BN. The nanostructure may be epitaxially grown, e.g., via implementation of an MBE procedure in an act 612. As described herein, the nanostructure may be grown in N-rich conditions in an act 614. In one example, the nanostructure was grown using a relatively low B deposition rate (less than 0.05 Å/s) and nitrogen-rich plasma parameters (a flow rate of 1.5 sccm with a forward power of 350 W). The growth may be conducted at elevated temperatures in an act 616. For example, the growth temperature may be about 1300° C. in some cases. In one example, the growth duration was between 30 minutes and one hour.

The layered material structure may include any number of monolayers. As a layered material, adjacent monolayers are bonded to one another via van der Waals forces. In some cases, one of the monolayers is in contact with the substrate. In other cases, an intermediary layer is disposed between the layered material structure and the substrate. For instance, a growth template may be disposed between the layered material structure and the substrate.

The layered material structure may be composed of, or otherwise include, h-BN. Alternative or additional layered or two-dimensional (2D) materials may be used. For instance, the layered material structure may be composed of, or otherwise include, MoS₂, Tungsten disulfide (WS₂), Tungsten diselenide (WSe₂), and graphene. Still other layered materials may be used, including, for instance, GaSe, InSe, black phosphorus.

The method 600 includes an act 618 in which a semiconductor stack of the heterostructure is epitaxially grown. In some cases, the act 618 includes the implementation of one or more procedures in preparation for the growth of the semiconductor stack in an act 620. For instance, the wafer having the nanostructure may be diced and/or cleaned. In one example, a h-BN/Ni wafer (2″ in diameter) was manually diced into 1.5 cm² pieces and a standard solvent cleaning was implemented prior to re-loading into the MBE system.

The act 618 may include the implementation of an epitaxial growth procedure in an act 622. In some cases, the act 622 includes implementation of a plasma-assisted MBE procedure. For instance, the act 622 (and/or other growth acts described herein) may use a Veeco GENxplor MBE system, equipped with a radio frequency (RF) nitrogen plasma source for active nitrogen supply (N′). Alternative or additional procedures may be implemented, including, for instance, a MOCVD procedure.

The act 618 may include an act 624 in which dopant sources are controlled. For example, Si and Mg dopant sources may be controlled to form p-AlN, n-AlN, and n-AlGaN layers of the semiconductor stack.

In the example of FIG. 6, the method 600 includes an act 626 in which a contact is formed. As described above, the contact may include one or more metal layers, such as Ti and Au. The act 626 may thus include the implementation of one or more deposition and lift-off procedures.

In the example of FIG. 6, the method 600 includes an act 628 in which one or more additional device structures are formed. The device structure(s) may or may not be part of the heterostructure. For instance, the device structures may include additional layered materials of a conducting, semiconducting, or insulating nature. In other cases, one or more metal layers may be deposited and patterned to form one or more metal interconnects or other structures (e.g., source, drain, and gate electrodes).

The method 600 may include one or more additional acts. For instance, one or more acts may be configured or directed to forming additional structures of the device before or after transfer of the heterostructure to a device substrate. The additional structures may be supported by the device substrate. For instance, a gate electrode may be formed on an opposite side of the device substrate.

Described herein are examples of devices providing light emission in the far ultraviolet (UV)-C wavelengths, which is more effective and safer in containing the transmission of microbial diseases than traditional UV light. As described above, h-BN, despite an indirect energy bandgap, exhibited remarkably high room-temperature quantum efficiency (about 60%), which is orders of magnitude higher than that of any other indirect bandgap material, and which was enabled by strong excitonic effects and efficient exciton-phonon interactions. A variety of devices may be realized, including, far UV-C optoelectronic devices and quantum photonic devices having 2D semiconductor active regions.

The term “about” is used herein in a manner to include deviations from a specified value that would be understood by one of ordinary skill in the art to effectively be the same as the specified value due to, for instance, the absence of appreciable, detectable, or otherwise effective difference in operation, outcome, characteristic, or other aspect of the disclosed methods and devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A device comprising:
a substrate; and
a heterostructure supported by the substrate, the heterostructure comprising:
a semiconductor stack supported by the substrate, the semiconductor stack defining a junction; and
a nanostructure comprising a layered material, the nanostructure being disposed between the semiconductor stack and the substrate and configured such that radiative recombination of charge carriers reaching the nanostructure via the junction and the substrate is achieved.

2. The device of claim 1, wherein the nanostructure has a bandgap such that the radiative recombination emits far UV-C light.

3. The device of claim 1, wherein the semiconductor stack and the nanostructure are configured to establish a light emitter.

4. The device of claim 1, wherein the semiconductor stack and the nanostructure are configured to establish a single photon source.

5. The device of claim 1, wherein the nanostructure is configured as a two-dimensional active region.

6. The device of claim 1, wherein the layered material is an indirect bandgap semiconductor material.

7. The device of claim 1, wherein the layered material has an ultrawide bandgap.

8. The device of claim 1, wherein the layered material comprises hexagonal boron nitride.

9. The device of claim 1, wherein the nanostructure is a monolayer of the layered material.

10. The device of claim 1, wherein the junction is defined by a p-i-n layer arrangement of the semiconductor stack.

11. The device of claim 1, wherein the semiconductor stack comprises a layer of a wide bandgap semiconductor material.

12. The device of claim 1, wherein the substrate comprises nickel.

13. The device of claim 1, wherein the semiconductor stack comprises a plurality of layers, each layer of the plurality of layers comprising a Ill-nitride semiconductor material.

14. The device of claim 1, wherein the semiconductor stack comprises a nanowire that projects outwardly from the substrate.

15. The device of claim 1, wherein the nanostructure is in contact with the substrate.

16. The device of claim 1, wherein the nanostructure is in contact with the semiconductor stack.

17. A device comprising:
a substrate; and
a heterostructure supported by the substrate, the heterostructure comprising:
a semiconductor stack supported by the substrate, the semiconductor stack defining a junction; and
a two-dimensional active region disposed between the semiconductor stack and the substrate, the two-dimensional active region being configured for photoemission upon charge carriers reaching the two-dimensional active region via the junction.

18. The device of claim 17, wherein the two-dimensional active region is configured as a monolayer.

19. The device of claim 17, wherein the two-dimensional active region comprises an indirect bandgap semiconductor material.

20. The device of claim 17, wherein the two-dimensional active region comprises hexagonal boron nitride.

21. The device of claim 17, wherein the semiconductor stack comprises a layer of a wide bandgap semiconductor material.

22. The device of claim 17, wherein the two-dimensional active region is in contact with the substrate.

23. The device of claim 17, wherein the two-dimensional active region is in contact with the semiconductor stack.

24. A method of fabricating a device, the method comprising:
forming a nanostructure on a substrate, the nanostructure comprising a layered material; and
forming a semiconductor stack on the nanostructure such that the nanostructure is disposed between the semiconductor stack and the substrate, such that the semiconductor stack defines a junction, and such that radiative recombination of charge carriers reaching the nanostructure via the junction and the substrate is achieved.

25. The method of claim 24, wherein forming the nanostructure comprises growing the nanostructure epitaxially.

26. The method of claim 24, wherein forming the semiconductor stack comprises growing a plurality of semiconductor layers of the semiconductor stack epitaxially.

27. A light emitting device comprising:
a substrate; and
a heterostructure supported by the substrate, the heterostructure comprising an active region configured for photoemission;
wherein the active region comprises hexagonal boron nitride.
